(19) United States
(12) Patent Application Publication
(10) Pub. No.: US 2020/0218161 A1
(43) Pub. Date: Jul. 9, 2020

(54) RESIST PATTERN-FORMING METHOD AND SUBSTRATE-TREATING METHOD

(71) Applicant: JSR CORPORATION, Tokyo (JP)

(72) Inventors: Ryuichi SERIZAWA, Tokyo (JP); Nozomi SATOU, Tokyo (JP); Yuusuke OOTSUBO, Tokyo (JP); Tomoya TAJI, Tokyo (JP); Tomoaki SEKO, Tokyo (JP); Souta NISHIMURA, Tokyo (JP)

(73) Assignee: JSR CORPORATION, Tokyo (JP)

(21) Appl. No.: 16/819,315

(22) Filed: Mar. 16, 2020

Related U.S. Application Data
(63) Continuation of application No. PCT/JP2018/033892, filed on Sep. 12, 2018.

(30) Foreign Application Priority Data
Sep. 19, 2017 (JP) 2017-179588

(51) Int. Cl. G03F 7/20; G03F 7/004

(52) U.S. Cl. CPC G03F 7/70033; G03F 7/2004; G03F 7/0043

(57) ABSTRACT

A resist pattern-forming method includes treating a surface layer of a substrate with an ultraviolet ray, plasma, water, an alkali, an acid, hydrogen peroxide, ozone, or a combination thereof. The surface layer includes at least one metal element. A resist composition is applied on a surface of the surface layer to provide a resist film directly or indirectly on the surface. The resist film is exposed to an extreme ultraviolet ray or an electron beam. The resist film exposed is developed. The at least one metal element preferably belongs to period 3 to period 7 of group 3 to group 15 in periodic table.

### CROSS-REFERENCE TO RELATED APPLICATIONS

The present application is a continuation application of International Application No. PCT/JP2018/033892, filed Sep. 12, 2018, which claims priority to Japanese Patent Application No. 2017-179588, filed Sep. 19, 2017. The contents of these applications are incorporated herein by reference in their entirety.

### BACKGROUND OF THE INVENTION

### Field of the Invention

The present invention relates to a resist pattern-forming method and a substrate-treating method.

### Description of the Related Art

In pattern formation of semiconductor elements and the like, resist processes are employed in which a resist film laminated on a substrate is exposed and developed, and the substrate is etched using a resultant resist pattern as a mask (see Japanese Unexamined Patent Application, Publication No. 2004-310019 and PCT International Publication No. 2012/039337). In recent years, highly enhanced integration of semiconductor devices has advanced further, and exposure light to be used tends to have a shorter wavelength, as from a KrF excimer laser beam (248 nm) or an ArF excimer laser beam (193 nm) to an extreme ultraviolet ray (13.5 nm; EUV) or an electron beam (EB).

### SUMMARY OF THE INVENTION

According to an aspect of the present invention, a resist pattern-forming method includes treating a surface layer of a substrate with an ultraviolet ray, plasma, water, an alkali, an acid, hydrogen peroxide, ozone, or a combination thereof. The surface layer includes at least one metal element. A resist composition is applied on a surface of the surface layer to provide a resist film directly or indirectly on the surface. The resist film is exposed to an extreme ultraviolet ray or an electron beam. The resist film exposed is developed.

According to another aspect of the present invention, a substrate-treating method includes treating a surface layer of a substrate on which a resist pattern is to be formed by exposure to an extreme ultraviolet ray or an electron beam, with an ultraviolet ray, plasma, water, an alkali, an acid, hydrogen peroxide, ozone, or a combination thereof. The surface layer includes at least one metal element.

### DESCRIPTION OF EMBODIMENTS

According to an embodiment of the invention, a resist pattern-forming method includes: treating at least one surface of a substrate containing a metal element in at least one surface layer, the at least one surface containing the metal element, wherein the treating is one, or two or more of exposure to an ultraviolet ray, exposure to plasma, contact with water, contact with an alkali, contact with an acid, contact with hydrogen peroxide, and contact with ozone; applying a resist composition on the at least one surface treated in the treating; exposing a resist film formed by the applying to an extreme ultraviolet ray or an electron beam; and developing the resist film exposed.

According to another embodiment of the present invention, a substrate-treating method is a method for use in forming a resist pattern by exposure to an extreme ultraviolet ray or an electron beam, wherein a substrate containing a metal element in at least one surface layer is treated, and the substrate-treating method includes treating at least one surface of the substrate, the at least one surface containing the metal element, wherein the treating is one, or two or more of exposure to an ultraviolet ray, exposure to plasma, contact with water, contact with an alkali, contact with an acid, contact with hydrogen peroxide, and contact with ozone.

The resist pattern-forming method and the substrate-treating method of the embodiments of the present invention enable a resist pattern superior in resolution to be obtained with high sensitivity. Accordingly, these can be suitably used for extreme ultraviolet ray lithography or electron beam lithography, as well as for manufacture of semiconductor devices, for which microfabrication is expected to progress further hereafter, and the like.

Hereinafter, a resist pattern-forming method and a substrate-treating method according to embodiments of the present invention will be described.

### Resist Pattern-Forming Method

The resist pattern-forming method includes the steps of: preparing a substrate containing a metal element in at least one surface layer (hereinafter, may be also referred to as “preparing step”); treating at least one surface of the substrate containing the metal element, the at least one surface containing the metal element, wherein the treating is one, or two or more of exposure to an ultraviolet ray, exposure to plasma, contact with water, contact with an alkali, contact with an acid, contact with hydrogen peroxide, and contact with ozone (hereinafter, may be also referred to as “treating step”); applying a resist composition on the at least one surface treated in the treating (hereinafter, may be also referred to as “applying step”); exposing a resist film formed by the treating to an extreme ultraviolet ray or an electron beam (hereinafter, may be also referred to as “exposing step”); and developing the resist film exposed (hereinafter, may be also referred to as “developing step”). The resist pattern-forming method may further include etching the substrate using a resist pattern formed by the developing as a mask (hereinafter, may be also referred to as “etching step”).

The resist pattern-forming method including the above steps enables formation of a resist pattern superior in resolution with high sensitivity. Although not necessarily clarified and without wishing to be bound by any theory, the reason for achieving the effects described above due to the resist pattern-forming method having the constitution described above may be supposed as in the following, for example. To explain specifically, it is considered that using the substrate containing the metal element in the at least one surface, the extreme ultraviolet ray or the electron beam which is radiated by extreme ultraviolet ray lithography or electron beam lithography is absorbed by the metal element included in the at least one surface of the substrate; accordingly, secondary electrons and the like are generated, and the secondary electrons impart sensitivity to the resist film. It is considered that by conducting the exposure and/or contact in the treating according to the resist pattern-forming method, electronic states, coordination states, and the like in metal atoms of the at least one surface of the substrate change; as a result, a degree of secondary electron generation increases and the sensitivity of the resist film due to the extreme ultraviolet ray or the electron beam improves, enabling the formation of the resist pattern superior in resolution with high sensitivity. Hereinafter, each step will be described.

Preparing Step

In this step, a substrate (hereinafter, may be also referred to as “substrate (P)”) containing a metal element in at least one surface layer is prepared. “Surface layer” as referred to herein means a region of up to 5 nm in depth from a surface of the substrate.

The substrate (P) is exemplified by a metal-containing substrate, a substrate having a layer (hereinafter, may be also referred to as “metal-containing layer (T)”) containing a metal element (hereinafter, may be also referred to as “metal element (a)”) in at least one face side, and the like. As the substrate, a patterned substrate with wiring grooves (trenches), plug grooves (vias), or the like may be used.

The metal-containing substrate is exemplified by a Ti-containing substrate such as a titanium-containing substrate, a titanium oxide-containing substrate, a titanium nitride-containing substrate, and the like; a Zr-containing substrate such as a zirconium oxide-containing substrate, a zirconium nitride-containing substrate, and the like; an Hf-containing substrate such as a hafnium oxide-containing substrate and the like; a Zn-containing substrate such as a zinc oxide-containing substrate and the like; an Al-containing substrate such as an aluminum oxide-containing substrate, an aluminum oxynitride-containing substrate, and the like; and the like.

The metal-containing layer (T) may be formed by applying a metal-containing composition (hereinafter, may be also referred to as “metal-containing composition (X)”), a chemical vapor deposition (CVD) procedure, a physical vapor deposition (PVD) procedure, an atomic layer deposition (ALD) procedure, or the like.

A procedure of applying the metal-containing composition (X) is exemplified by spin coating, roll coating, dip coating, and the like. A coating film formed by the applying of the metal-containing composition (X) may be heat-treated. The lower limit of a temperature of the heat treatment is preferably 90° C., and more preferably 150° C. The upper limit of the temperature is preferably 550° C., and more preferably 300° C. The lower limit of an average thickness of the metal-containing layer (T) to be formed is preferably 1 nm, and more preferably 3 nm. The upper limit of the average thickness is preferably 50 nm, and more preferably 30 nm.

The CVD procedure is exemplified by plasma-enhanced CVD, low-pressure CVD, and the like. The PVD procedure is exemplified by a sputtering procedure, an evaporation procedure, and the like. The metal-containing layer (T) to be formed by the CVD procedure, the PVD procedure, the ALD procedure, or the like is exemplified by a titanium oxide film, a titanium nitride film, a zirconium oxide film, an aluminum oxide film, an aluminum oxynitride film, a hafnium oxide film, and the like.

A base material of the substrate having the metal-containing layer (T) is exemplified by a base material having an insulating film of silicon oxide, silicon nitride, silicon oxynitride, polysiloxane, or the like; a resin base material; and the like. As the substrate having the metal-containing layer (T), for example, a silicon wafer or the like coated with a low-dielectric insulating film formed from “Black Diamond” available from AMAT, “SiLK” available from Dow Chemical, “LKD5109” available from JSR Corporation, or the like may be used.

The metal element (a) contained in the at least one surface layer of the substrate (P) is exemplified by a metal element belonging to period 3 to period 7 of group 3 to group 15 in periodic table, and the like. It is to be noted that the metal element (a) does not include metalloid elements such as boron, silicon, arsenic, and the like.

Examples of the metal element (a) belonging to group 3 include scandium, yttrium, lanthanum, cerium, and the like;

examples of the metal element (a) belonging to group 4 include titanium, zirconium, hafnium, and the like;

examples of the metal element (a) belonging to group 5 include vanadium, niobium, tantalum, and the like;

examples of the metal element (a) belonging to group 6 include chromium, molybdenum, tungsten, and the like;

examples of the metal element (a) belonging to group 7 include manganese, rhenium, and the like;

examples of the metal element (a) belonging to group 8 include iron, ruthenium, osmium, and the like;

examples of the metal element (a) belonging to group 9 include cobalt, rhodium, iridium, and the like;

examples of the metal element (a) belonging to group 10 include nickel, palladium, platinum, and the like;

examples of the metal element (a) belonging to group 11 include copper, silver, gold, and the like;

examples of the metal element (a) belonging to group 12 include zinc, cadmium, mercury, and the like;

examples of the metal element (a) belonging to group 13 include aluminum, gallium, indium, and the like;

examples of the metal element (a) belonging to group 14 include germanium, tin, lead, and the like; and

examples of the metal element (a) belonging to group 15 include antimony, bismuth, and the like.

The metal element (a) is preferably a metal element belonging to period 4 to period 7 of group 3 to group 15, more preferably a metal element belonging to period 4 to period 7 of group 4 to group 6, still more preferably the metal element belonging to group 4, and particularly preferably titanium or zirconium.

Metal-Containing Composition

The metal-containing composition (X) is exemplified by a composition containing: a compound (hereinafter, may be also referred to as “(A) compound” or “compound (A)”) having a metal-oxygen covalent bond; and a solvent (hereinafter, may be also referred to as “(B) solvent” or “solvent (B”), and the like.

The compound (A) may contain an element (hereinafter, may be also referred to as “other element”) other than the metal element (a) and oxygen. Examples of the other element include: metalloid elements such as boron and silicon; nonmetal elements such as carbon, hydrogen, nitrogen, phosphorus, sulfur, and halogens; and the like. Of these, carbon and/or hydrogen are/is preferred.

The lower limit of a percentage content of atoms of the metal element (a) in the compound (A) is preferably 10% by mass, more preferably 20% by mass, and still more preferably 30% by mass. The upper limit of the percentage content is preferably 50% by mass. The percentage content of the atoms of the metal element (a) may be determined by measurement in which a differential thermal balance (TG/DTA) is used.

The compound (A) is exemplified by a polynuclear complex having a bond of metal-oxygen-metal, and the like. The “polynuclear complex” as referred to herein means a complex having a plurality of metal atoms. Such a polynuclear complex can be synthesized by, for example, hydrolytic condensation of a metal-containing compound having a hydrolyzable group, as described later.

In a case in which the compound (A) is the polynuclear complex, the lower limit of a polystyrene-equivalent weight average molecular weight (Mw) of the compound (A) as determined by gel permeation chromatography (GPC) is preferably 1,000, more preferably 1,500, and still more preferably 2,000. The upper limit of the Mw is preferably 10,000, more preferably 8,000, and still more preferably 6,000.

Herein, the Mw of the compound (A) is a value determined by gel permeation chromatography (detector: differential refractometer) using GPC columns (“AWM-H”×2; “AW-H”×1; and “AW2500”×2, available from Tosoh Corporation) under an analytical condition involving a flow rate of 0.3 mL/min, an elution solvent of a mixture prepared by adding LiBr (30 mM) and citric acid (30 mM) to N,N′-dimethylacetamide, and a column temperature of 40° C., with mono-dispersed polystyrene as a standard.

The lower limit of a percentage content of the compound (A) with respect to the total solid content of the metal-containing composition (X) is preferably 70% by mass, more preferably 80% by mass, and still more preferably 90% by mass. The upper limit of the percentage content may be 100% by mass. When the percentage content of the compound (A) falls within the above range, coating characteristics of the metal-containing composition (X) can be further improved. The “total solid content” of the metal-containing composition (X) as referred to herein means components other than the solvent (B). The metal-containing composition (X) may contain one, or two or more types of the compound (A).

The compound (A) used may be a commercially available metal compound, or may be synthesized by, for example, a procedure of carrying out a hydrolytic condensation reaction by using a metal-containing compound having a hydrolyzable group (hereinafter, may be also referred to as “(b) metal-containing compound” or “metal-containing compound (b)”), or the like. In other words, the compound (A) may be derived from the metal-containing compound (b). The “hydrolytic condensation reaction” as referred to herein means a reaction in which a hydrolyzable group included in the metal-containing compound (b) is hydrolyzed to give —OH, and two —OHs thus obtained undergo dehydrative condensation to form —O—.

(b) Metal-Containing Compound

The metal-containing compound (b) may be: a metal compound having a hydrolyzable group (hereinafter, may be also referred to as “metal compound (I)”); a hydrolysis product of the metal compound (I); a hydrolytic condensation product of the metal compound (I); or a combination thereof. The metal compound (I) may be used either alone of one type, or in a combination of two or more types thereof.

The hydrolyzable group is exemplified by a halogen atom, an alkoxy group, an acyloxy group, or the like.

Examples of the halogen atom include a fluorine atom, a chlorine atom, a bromine atom, an iodine atom, and the like.

Examples of the alkoxy group include a methoxy group, an ethoxy group, an n-propoxy group, an isopropoxy group, a butoxy group, and the like.

Examples of the acyloxy group include an acetoxy group, an ethylyloxy group, a propionyloxy group, a butyryloxy group, a t-butyryloxy group, a t-amylyloxy group, an n-hexanecarbonyloxy group, an n-octanecarbonyloxy group, and the like.

As the hydrolyzable group, the alkoxy group is preferred, and an isopropoxy group or a butoxy group is more preferred.

In a case in which the metal-containing compound (b) is a hydrolytic condensation product of the metal compound (I), the hydrolytic condensation product of the metal compound (I) may be a hydrolytic condensation product of the metal compound (I) containing the metal element (a) with a compound containing a metalloid element, within a range not leading to impairment of the effects of the present invention. In other words, the hydrolytic condensation product of the metal compound (I) may include a metalloid element within a range not leading to impairment of the effects of the present invention. Examples of the metalloid element include boron, silicon, arsenic, tellurium, and the like. A percentage content of the metalloid atom in the hydrolytic condensation product of the metal compound (I) with respect to a total amount of the atoms of the metal element (a) and the metalloid atoms in the hydrolytic condensation product is typically less than 50 atom %, preferably no greater than 30 atom %, and more preferably no greater than 10 atom %.

The metal compound (I) is exemplified by compounds represented by the following formula (1) (hereinafter, may be also referred to as a “metal compound (I-1)”), and the like.

LₐMY_{b} (1)

In the above formula (1), M represents a metal atom; L represents a ligand; “a” is an integer of 0 to 6, wherein in a case in which “a” is no less than 2, a plurality of Ls are identical or different; Y represents a hydrolyzable group selected from a halogen atom, an alkoxy group, or an acyloxy group; and b is an integer of 2 to 6, wherein a plurality of Ys are identical or different, and L is a ligand not falling under the category of Y.

The metal atom represented by M may be exemplified by atoms similar to those exemplified as the atom of the metal element (a) contained in the at least one surface layer of the substrate (P), and the like.

The ligand represented by L is exemplified by a monodentate ligand and a polydentate ligand.

Exemplary monodentate ligands include a hydroxo ligand, a carboxy ligand, an amido ligand, an amine ligand, an ammonia ligand, an olefin ligand, and the like.

Examples of the amido ligand include an unsubstituted amido ligand (NH₂), a methylamido ligand (NHMe), a dimethylamido ligand (NMe₂), a diethylamido ligand (NEt₂), a dipropylamido ligand (NPr₂), and the like.

Examples of the amine ligand include a pyridine ligand, a trimethylamine ligand, a piperidine ligand, and the like.

Examples of the olefin ligand include linear olefins such as ethylene and propylene; cyclic olefins such as cyclopentene, cyclohexene, and norbornene; and the like.

Examples of the polydentate ligand include a ligand derived from a hydroxy acid ester, a ligand derived from a β-diketone, a ligand derived from a β-keto ester, a ligand derived from an α,α-dicarboxylic acid ester, a hydrocarbon having multiple π bonds, diphosphine, and the like.

Examples of the hydroxy acid ester include glycolic acid esters, lactic acid esters, 2-hydroxycyclohexane-1-carboxylic acid esters, salicylic acid esters, and the like.

Examples of the β-diketone include 2,4-pentanedione, 3-methyl-2,4-pentanedione, 3-ethyl-2,4-pentanedione, and the like.

Examples of the β-keto ester include acetoacetic acid esters, α-alkyl-substituted acetoacetic acid esters, β-ketopentanoic acid esters, benzoylacetic acid esters, 1,3-acetonedicarboxylic acid esters, and the like.

Examples of the α,α-dicarboxylic acid ester include malonic acid diesters, α-alkyl-substituted malonic acid diesters, α-cycloalkyl-substituted malonic acid diesters, α-aryl-substituted malonic acid diesters, and the like.

Examples of the hydrocarbon having multiple π bonds include: chain dienes such as butadiene and isoprene; cyclic dienes such as cyclopentadiene, methylcyclopentadiene, pentamethylcyclopentadiene, cyclohexadiene, and norbornadiene; aromatic hydrocarbons such as benzene, toluene, xylene, hexamethylbenzene, naphthalene, and indene; and the like.

Examples of the diphosphine include 1,1-bis(diphenylphosphino)methane, 1,2-bis(diphenylphosphino)ethane, 1,3-bis(diphenylphosphino)propane, 2,2′-bis(diphenylphosphino)-1,1′-binaphthyl, 1,1′-bis(diphenylphosphino)ferrocene, and the like.

In the formula (1), “a” is preferably 0 to 3, more preferably 0 to 2, still more preferably 1 or 2, and particularly preferably 2. When “a” is a value described above, stability of the compound (A) can be appropriately improved, and as a result, the sensitivity in the resist pattern-forming method can be further increased.

The hydrolyzable group which may be represented by Y is exemplified by groups similar to those exemplified as the hydrolyzable group in the metal-containing compound (b), and the like.

In the above formula (1), b is preferably 2 to 4, more preferably 2 or 3, and still more preferably 2. When b is a value described above, the molecular weight of the compound (A) that is a hydrolytic condensation product can be more appropriately increased, and as a result, the sensitivity in the resist pattern-forming method can be further increased.

As the metal-containing compound (b), a metal alkoxide that is neither hydrolyzed nor hydrolytically condensed, and a metal alkoxide that has a ligand and is neither hydrolyzed nor hydrolytically condensed are preferred.

Examples of the metal-containing compound (b) include:

titanium-containing compounds such as diisopropoxybis(2,4-pentanedionato) titanium(IV), tetra-n-butoxy titanium(IV), tetra-n-propoxy titanium(IV), titanium(IV) tri-n-butoxymonostearate, a titanium(IV) butoxide oligomer, aminopropyltrimethoxy titanium(IV), triethoxymono(2,4-pentanedionato) titanium(IV), tri-n-propoxymono(2,4-pentanedionato) titanium(IV), triisopropoxymono(2,4-pentanedionato) titanium, and di-n-butoxybis(2,4-pentanedionato) titanium(IV);

zirconium-containing compounds such as dibutoxybis(ethylacetoacetate) zirconium(IV), di-n-butoxybis(2,4-pentanedionato) zirconium(IV), tetra-n-butoxy zirconium(IV), tetra-n-propoxy zirconium(IV), tetraisopropoxy zirconium(IV), aminopropyltriethoxy zirconium(IV), 2-(3,4-epoxycyclohexyl)ethyltrimethoxy zirconium(IV), γ-glycidoxypropyltrimethoxy zirconium(IV), 3-isocyanopropyltrimethoxy zirconium(IV), triethoxymono(2,4-pentanedionato) zirconium(IV), tri-n-propoxymono(2,4-pentanedionato) zirconium(IV), triisopropoxymono(2,4-pentanedionato) zirconium(IV), tri(3-methacryloxypropyl)methoxy zirconium(IV), and tri(3-acryloxypropyl)methoxy zirconium(IV);

hafnium-containing compounds such as diisopropoxybis(2,4-pentanedionato) hafnium(IV), tetrabutoxy hafnium(IV), tetraisopropoxy hafnium(IV), tetraethoxy hafnium(IV), and dichlorobis(cyclopentadienyl) hafnium(IV);

tantalum-containing compounds such as tetrabutoxy tantalum(IV), pentabutoxy tantalum(V), and pentaethoxy tantalum(V);

tungsten-containing compounds such as tetrabutoxy tungsten(IV), pentabutoxy tungsten(V), pentamethoxy tungsten(V), hexabutoxy tungsten(VI), hexaethoxy tungsten(VI), and dichlorobis(cyclopentadienyl)tungsten(IV);

iron-containing compounds such as iron chloride(III);

ruthenium-containing compounds such as diacetato[(S)-(−)-2,2′-bis(diphenylphosphino)-1,1′-binaphthyl]ruthenium(II);

cobalt-containing compounds such as dichloro[ethylenebis(diphenylphosphine)]cobalt(II);

zinc-containing compounds such as diisopropoxy zinc(II) and zinc(II) acetate;

indium-containing compounds such as indium(III) acetate and triisopropoxy indium(III);

tin-containing compounds such as tetraethyldiacetoxy stannoxane, tetrabutoxy tin(IV), tetraisopropoxy tin(IV), and t-butyltris(diethylamide) tin(IV); and

germanium-containing compounds such as tetraisopropoxy germanium(IV).

Upon a synthesis reaction of the compound (A), in addition to the metal compound (I), a compound that can be the monodentate ligand or the polydentate ligand, a compound that can be a bridging ligand, etc. may also be added. The compound that can be the bridging ligand is exemplified by a compound having a hydroxy group, an isocyanate group, an amino group, an ester group, or an amide group each in a plurality of number, and the like.

A procedure for carrying out the hydrolytic condensation reaction using the metal-containing compound (b) may be exemplified by: a procedure of causing a hydrolytic condensation reaction in the metal-containing compound (b) in a solvent containing water; and the like. In this case, another compound having a hydrolyzable group may be added as needed. Also, an acid such as acetic acid may be added as a catalyst of the hydrolytic condensation reaction. The lower limit of an amount of water used for the hydrolytic condensation reaction with respect to the hydrolyzable group included in the metal-containing compound (b) and the like is preferably 0.2 times a molar amount, more preferably an equimolar amount, and still more preferably 3 times the molar amount. The upper limit of the amount of water is preferably 20 times the molar amount, more preferably 15 times the molar amount, and still more preferably 10 times the molar amount.

The solvent for use in the synthesis reaction of the compound (A) is not particularly limited, and solvents similar to those exemplified in connection with the solvent (B) described later may be used. Of these, ester solvents, alcohol solvents, and/or ether solvents are preferred; alcohol solvents and/or ether solvents are more preferred; ether solvents having glycol structures are still more preferred; and propylene glycol monomethyl ether and/or propylene glycol monoethyl ether are/is particularly preferred.

In the case in which the solvent is used in the synthesis reaction of the compound (A), the solvent used may be either removed after completion of the reaction, or directly used as the solvent in the metal-containing composition (X) without removal thereof.

The lower limit of a temperature of the synthesis reaction of the compound (A) is preferably 0° C., and more preferably 10° C. The upper limit of the temperature is preferably 150° C., and more preferably 100° C.

The lower limit of a time period of the synthesis reaction of the compound (A) is preferably 1 min, more preferably 10 min, and still more preferably 1 hour. The upper limit of the time period is preferably 100 hrs, more preferably 50 hrs, and still more preferably 10 hrs.

The solvent (B) is not particularly limited as long as it is capable of dissolving or dispersing the compound (A) and other component(s) which may be contained as needed. The solvent (B) is exemplified by alcohol solvents, ketone solvents, ether solvents, ester solvents, nitrogen-containing solvents, water, and the like. The solvent (B) may be used alone of one type, or in a combination of two or more types thereof.

Examples of the alcohol solvents include: monohydric alcohol solvents such as methanol, ethanol, n-propanol, isopropanol, n-butanol, and isobutanol; polyhydric alcohol solvents such as ethylene glycol, 1,2-propylene glycol, diethylene glycol, and dipropylene glycol; and the like.

Examples of the ketone solvents include acetone, methyl ethyl ketone, methyl-n-propyl ketone, methyl isopropyl ketone, cyclohexanone, and the like.

Examples of the ether solvents include diethyl ether, diisopropyl ether, ethylene glycol dibutyl ether, diethylene glycol monomethyl ether, diethylene glycol monoethyl ether, diethylene glycol diethyl ether, propylene glycol monomethyl ether, propylene glycol monoethyl ether, propylene glycol monopropyl ether, tetrahydrofuran, and the like.

Examples of the ester solvents include ethyl acetate, γ-butyrolactone, n-butyl acetate, isobutyl acetate, sec-butyl acetate, amyl acetate, ethylene glycol monomethyl ether acetate, ethylene glycol monoethyl ether acetate, diethylene glycol monomethyl ether acetate, diethylene glycol monoethyl ether acetate, propylene glycol monomethyl ether acetate, propylene glycol monoethyl ether acetate, dipropylene glycol monomethyl ether acetate, dipropylene glycol monoethyl ether acetate, ethyl propionate, n-butyl propionate, methyl lactate, ethyl lactate, and the like.

Examples of the nitrogen-containing solvents include N,N-dimethylformamide, N,N-dimethylacetamide, N-methylpyrrolidone, and the like.

Of these, the ether solvents, the ester solvents, and/or water are/is preferred, and due to superior film formability, the ester solvents and/or the ether solvents having a glycol structure are preferred.

Examples of the ether solvents and the ester solvents having glycol structures include propylene glycol monomethyl ether, propylene glycol monoethyl ether, propylene glycol monopropyl ether, propylene glycol monomethyl ether acetate, propylene glycol monoethyl ether acetate, propylene glycol monopropyl ether acetate, and the like.

The lower limit of a percentage content of the ether solvent and the ester solvent having a glycol structure is preferably 20% by mass, more preferably 60% by mass, still more preferably 90% by mass, and particularly preferably 100% by mass.

The lower limit of a percentage content of the solvent (B) in the metal-containing composition (X) is preferably 80% by mass, more preferably 90% by mass, and still more preferably 95% by mass. The upper limit of the percentage content is preferably 99% by mass, and still more preferably 98% by mass.

The metal-containing composition (X) may contain, as the other component(s) apart from the compound (A) and the solvent (B), for example, an acid generating agent, a surfactant, and/or the like.

The acid generating agent is a compound that generates an acid due to irradiation with ultraviolet light and/or heating. The acid generating agent may be used either alone of one type, or in a combination of two or more types thereof.

Exemplary acid generating agents include onium salt compounds, N-sulfonyloxyimide compounds, and the like.

The onium salt compounds are exemplified by sulfonium salts, tetrahydrothiophenium salts, iodonium salts, ammonium salts, and the like.

Examples of the sulfonium salts include triphenylsulfonium trifluoromethanesulfonate, triphenylsulfonium nonafluoro-n-butanesulfonate, 4-cyclohexylphenyldiphenylsulfonium trifluoromethanesulfonate, and the like.

Examples of the tetrahydrothiophenium salts include tetrahydrothiophenium salts described in paragraph [0111] of Japanese Unexamined Patent Application, Publication No. 2014-037386, and more specific examples include 1-(4-n-butoxynaphthalene-1-yl)tetrahydrothiophenium trifluoromethanesulfonate, 1-(4-n-butoxynaphthalene-1-yl)tetrahydrothiophenium nonafluoro-n-butanesulfonate, 1-(4-n-butoxynaphthalene-1-yl)tetrahydrothiophenium 2-bicyclo[2.2.1]hept-2-yl-1,1,2,2-tetrafluoroethanesulfonate, and the like.

Examples of the iodonium salts include iodonium salts described in paragraph

of Japanese Unexamined Patent Application, Publication No. 2014-037386, and more specific examples include diphenyliodonium trifluoromethanesulfonate, diphenyliodonium nonafluoro-n-butanesulfonate, diphenyliodonium 2-bicyclo[2.2.1]hept-2-yl-1,1,2,2-tetrafluoroethanesulfonate, bis(4-t-butylphenyl)iodonium nonafluoro-n-butanesulfonate, and the like.

Examples of the ammonium salts include trimethylammonium nonafluoro-n-butanesulfonate, triethylammonium nonafluoro-n-butanesulfonate, and the like.

The N-sulfonyloxyimide compounds are exemplified by the N-sulfonyloxyimide compounds described in paragraph [0113] of Japanese Unexamined Patent Application, Publication No. 2014-037386, and more specific examples include N-(trifluoromethanesulfonyloxy)bicyclo[2.2.1]hept-5-ene-2,3-dicarboxyimide, N-(nanofluoro-n-butanesulfonyloxy)bicyclo[2.2.1]hept-5-ene-2,3-dicarboxyimide, N-(2-bicyclo[2.2.1]hept-2-yl-1,1,2,2-tetrafluoroethanesulfonyloxy)bicyclo[2.2.1]hept-5-ene-2,3-dicarboxyimide, and the like.

In the case in which the metal-containing composition (X) contains the acid generating agent, the lower limit of a content of the acid generating agent with respect to 100 parts by mass of the compound (A) is preferably 0.01 parts by mass, more preferably 0.1 parts by mass, still more preferably 0.5 parts by mass, and particularly preferably 1 part by mass. The upper limit of the content is preferably 10 parts by mass, more preferably 5 parts by mass, and still more preferably 2 parts by mass.

In a case in which the metal-containing composition (X) contains the other component(s) apart from the acid generating agent, the upper limit of a content of the other components with respect to 100 parts by mass of the compound (A) is preferably 1 part by mass, more preferably 0.5 parts by mass, and still more preferably 0.1 parts by mass.

Preparation Procedure of Metal-Containing Composition

A preparation method of the metal-containing composition (X) is not particularly limited; it may be prepared by, for example, mixing at a predetermined ratio the compound (A), the solvent (B), and the other component(s) which may be contained as needed, and preferably filtering through a filter having a pore size of no greater than 0.2 μm a mixed solution thus obtained.

The lower limit of a solid content concentration of the metal-containing composition (X) is preferably 0.01% by mass, more preferably 0.05% by mass, still more preferably 0.1% by mass, and particularly preferably 0.2% by mass. The upper limit of the solid content concentration is preferably 20% by mass, more preferably 10% by mass, still more preferably 5% by mass, and particularly preferably 3% by mass. The “solid content concentration” of the metal-containing composition (X) as referred to herein means a value (% by mass) as determined by: baking 0.5 g of the metal-containing composition (X) at 250° C. for 30 min; measuring a mass of the solid content in the metal-containing composition (X); and dividing the mass of the solid content by the mass of the metal-containing composition (X).

Treating Step

In this step, the at least one surface of the substrate (P), the at least one surface containing the metal element (a), is treated, wherein the treating is one, or two or more of exposure to an ultraviolet ray, exposure to plasma, contact with water, contact with an alkali, contact with an acid, contact with hydrogen peroxide, and contact with ozone.

In this step, only one treatment from among the exposure to an ultraviolet ray, exposure to plasma, contact with water, contact with an alkali, contact with an acid, contact with hydrogen peroxide, and contact with ozone may be carried out; or two or more treatments thereof may be carried out either sequentially or simultaneously. Hereinafter, each step will be described.

Exposure to Ultraviolet Ray

The ultraviolet ray is an electromagnetic wave having a wavelength of no less than 10 nm and no greater than 400 nm.

The lower limit of the wavelength of the ultraviolet ray is preferably 13 nm, and more preferably 150 nm. The upper limit of the wavelength is preferably 370 nm, and more preferably 255 nm.

The lower limit of a time period of the exposure to the ultraviolet ray is preferably 10 sec, more preferably 30 sec, and still more preferably 1 min. The upper limit of the time period of the exposure is preferably 10 hrs, more preferably 2 hrs, and still more preferably 30 min.

The lower limit of a surface temperature of the substrate (P) during the exposure to the ultraviolet ray is not particularly limited, and is typically 0° C., and preferably 10° C. The upper limit of the surface temperature is not particularly limited, and is typically 150° C., and preferably 50° C.

In terms of a region to be exposed to the ultraviolet ray, an entirety of the at least one surface of the substrate, the at least one surface containing the metal element, may be exposed, or a part of the at least one surface may be exposed. Removability of a metal-containing film on a surface of an edge portion of the base material can be altered by not exposing the surface of the edge portion of the base material.

An atmosphere around the at least one surface of the substrate (P) during the exposure to the ultraviolet ray is not particularly limited, and the exposure may be conducted either in air or in an inert gas such as nitrogen or the like. In a case in which the atmosphere contains oxygen gas (O₂) and the wavelength of the ultraviolet ray is no greater than 200 nm, ozone (O₃) is generated, and contact occurs between the ozone and the at least one surface of the substrate (P).

A procedure of conducting the exposure to the ultraviolet ray is exemplified by a procedure in which a radiation light source is used such as an Xe excimer lamp (center wavelength of emission: 172 nm), a low-pressure mercury lamp (center wavelength of emission: 185 nm, 254 nm), an ultraviolet ray LED lamp (center wavelength of emission: 250 nm to 400 nm), or the like. The lower limit of an irradiation intensity of the ultraviolet ray during the exposure is preferably 1 mW/cm², and more preferably 5 mW/cm². The upper limit of the irradiation intensity is preferably 200 mW/cm², and more preferably 50 mW/cm². Examples of an ultraviolet ray irradiation device include an apparatus having a pedestal on which the substrate is mounted and an ultraviolet ray irradiation unit by which the substrate on the pedestal is irradiated with the ultraviolet ray, and the like.

The exposure to the ultraviolet ray may be conducted once or a plurality of times.

Exposure to Plasma

The plasma is a gas that has been plasmatized. Examples of the gas include: fluorine-based gases such as CHF₃, CF₄, C₂F₆, C₃F₈, and SF₆; chlorine-based gases such as Cl₂ and BCl₃; oxygen-based gases such as O₂, O₃, and H₂O; reducing gases such as H₂, NH₃, CO, CO₂, CH₄, C₂H₂, C₂H₄, C₂H₆, C₃H₄, C₃H₆, C₃H₈, HF, HI, HBr, HCl, NO, NH₃, and BCl₃; and the like. These gases may also be used as a mixture.

A procedure of conducting the exposure to the plasma is exemplified by a direct procedure in which the substrate (P) is placed in an atmosphere of the gas and then plasma is discharged, and the like. As conditions for the exposure to the plasma, typically, a flow rate of 02 is no less than 500 cc/min and no greater than 100 cc/min, and an electric power feed is no less than 100 W and no greater than 1,500 W.

The lower limit of a time period of the exposure to the plasma is preferably 10 sec, more preferably 30 sec, and still more preferably 1 min. The upper limit of the time period of the exposure is preferably 10 min, more preferably 5 min, and still more preferably 2 min.

The lower limit of the surface temperature of the substrate (P) during the exposure to the plasma is not particularly limited, and is typically 0° C., and preferably 10° C. The upper limit of the surface temperature is not particularly limited, and is typically 100° C., and preferably 50° C.

The exposure to the plasma may be conducted once or a plurality of times.

Contact with Water

The water is preferably pure water, but a small amount of a water-soluble organic solvent, a surfactant, and/or the like may be contained within a range not leading to impairment of the effects of the present invention.

The lower limit of a time period of conducting the contact with water is typically 1 sec, and preferably 1 min. The upper limit of the time period of conducting the contact with water is typically 1 hour, and preferably 30 min.

The lower limit of the surface temperature of the substrate (P) when conducting the contact with water is typically greater than 0° C., and preferably 10° C. The upper limit of the surface temperature is typically less than 100° C., and preferably 40° C.

A procedure for bringing water into contact with the at least one surface of the substrate (P) is not particularly limited, and is exemplified by: a dipping procedure in which the substrate (P) is immersed for a given time period in water charged in a container; a puddle procedure in which water is placed to form a dome-shaped bead by way of the surface tension on the at least one surface of the substrate (P) and kept still for a given time period; a spraying procedure in which water is sprayed onto the at least one surface of the substrate (P); a dynamic dispensing procedure in which water is continuously discharged onto the substrate (P), which is rotated at a constant speed, while a discharge nozzle is scanned at a constant speed; and the like.

The contact with water may be conducted once or a plurality of times.

Contact with Alkali

The contact with an alkali is typically conducted using an alkali-containing solution (hereinafter, may be also referred to as “alkali solution”). Examples of the alkali include: organic amines such as ammonia, methylamine, dimethylamine, trimethylamine, ethylamine, diethylamine, triethylamine, and tetraalkylammonium compounds; inorganic alkali compounds such as sodium hydroxide, potassium hydroxide, sodium carbonate, sodium silicate, and sodium metasilicate; and the like. Examples of the tetraalkylammonium compounds include tetraalkylammonium hydroxides such as tetramethylammonium hydroxide (TMAH) and tetraethylammonium hydroxide, and the like. Examples of the alkali solution include aqueous alkali solutions in which these alkalis are each dissolved in water, and the like. The aqueous alkali solution may contain a small amount of a water-soluble organic solvent a, surfactant, and/or the like within a range not leading to impairment of the effects of the present invention. The aqueous alkali solution preferably does not contain either hydrogen fluoride and salts thereof or salts of a fluoride compound.

The lower limit of a concentration of the alkali in the alkali solution is preferably 0.1% by mass, and more preferably 0.5% by mass. The upper limit of the concentration is preferably 40% by mass, and more preferably 30% by mass.

The upper limit of a pH of the alkali solution is preferably 14, and more preferably 13. The lower limit of the pH is preferably 9, and more preferably 10.

If the alkali solution further contains hydrogen peroxide, a degree of change in a state of the metal element of the at least one surface of the substrate (P) can be increased. As a content of hydrogen peroxide, a mass ratio of hydrogen peroxide with respect to the alkali in the alkali solution is, for example, no less than 1/500 and no greater than 500.

The lower limit of a time period of conducting the contact with the alkali is typically 1 sec, and preferably 1 min. The upper limit of the time period of conducting the contact with the alkali is typically 1 hour, and preferably 30 min.

The lower limit of the surface temperature of the substrate (P) when conducting the contact with the alkali is typically greater than 0° C., and preferably 10° C. The upper limit of the surface temperature is typically less than 100° C., and preferably 40° C.

A procedure for the contact with the alkali is exemplified by procedures similar to the procedures for the contact with water, and the like.

The contact with the alkali may be conducted once, or a plurality of times. After conducting the contact with the alkali, the at least one surface of the substrate (P) is preferably rinsed with pure water or the like.

Contact with Acid

The contact with an acid is typically conducted using an acid-containing solution (hereinafter, may be also referred to as “acid solution”). Examples of the acid include inorganic acids such as sulfuric acid, hydrochloric acid, and hydrofluoric acid; organic acids such as p-toluenesulfonic acid; and the like. Examples of the acid solution include aqueous acid solutions in which these acids are each dissolved, and the like. These acid aqueous solutions may contain a small amount of a water-soluble organic solvent, a surfactant, and/or the like within a range not leading to impairment of the effects of the present invention.

The lower limit of a concentration of the acid in the acid solution is preferably 0.1% by mass, and more preferably 0.5% by mass. The upper limit of the concentration is preferably 40% by mass, and more preferably 30% by mass.

The upper limit of a pH of the acid solution is preferably 2, and more preferably 1. The lower limit of the pH is, for example, 0.

If the acid solution further contains hydrogen peroxide, a degree of change in a state of the metal element of the at least one surface of the substrate (P) can be increased. As a content of hydrogen peroxide, a mass ratio of hydrogen peroxide with respect to the acid in the acid solution is, for example, no less than 1/500 and no greater than 500.

The lower limit of a time period of conducting the contact with the acid is typically 1 sec, and preferably 1 min. The upper limit of the time period of conducting the contact with the acid is typically 1 hour, and preferably 30 min.

The lower limit of the surface temperature of the substrate (P) when conducting the contact with the acid is typically greater than 0° C., and preferably 10° C. The upper limit of the surface temperature is typically less than 100° C., and preferably 40° C.

A procedure for the contact with the acid is exemplified by procedures similar to the procedures for the contact with water, and the like.

The contact with the acid may be conducted once, or a plurality of times. After conducting the contact with the acid, the at least one surface of the substrate (P) is preferably rinsed with pure water or the like.

Contact with Hydrogen Peroxide

The contact with hydrogen peroxide is typically conducted using an aqueous hydrogen peroxide solution. The aqueous hydrogen peroxide solution may contain a small amount of a water-soluble organic solvent, a surfactant, and/or the like within a range not leading to impairment of the effects of the present invention.

The lower limit of a concentration of hydrogen peroxide in the aqueous hydrogen peroxide solution is preferably 1% by mass, and more preferably 3% by mass. The upper limit of the concentration is preferably 30% by mass, and more preferably 20% by mass.

The lower limit of a time period of conducting the contact with hydrogen peroxide is typically 1 sec, and preferably 1 min. The upper limit of the time period of conducting the contact with hydrogen peroxide is typically 1 hour, and preferably 30 min.

The lower limit of the surface temperature of the substrate (P) when conducting the contact with hydrogen peroxide is typically greater than 0° C., and preferably 10° C. The upper limit of the surface temperature is typically less than 100° C., and preferably 40° C.

A procedure for the contact with hydrogen peroxide is exemplified by procedures similar to the procedures for the contact with water, and the like.

The contact with hydrogen peroxide may be conducted once, or a plurality of times. After conducting the contact with the hydrogen peroxide water, the at least one surface of the substrate (P) is preferably rinsed with pure water or the like.

Contact with Ozone

The contact with ozone (O₃) is typically conducted using an ozone-containing gas. Alternatively, the contact with ozone can be conducted through irradiation with an ultraviolet ray having a wavelength of no greater than 200 nm in an oxygen-containing atmosphere so as to generate ozone.

The lower limit of an ozone concentration in the ozone-containing gas is preferably 0.1% by volume, and more preferably 0.5% by volume. The upper limit of the ozone concentration is preferably 10% by volume, and more preferably 5% by volume.

The lower limit of a time period of conducting the contact with ozone is typically 1 sec, and preferably 1 min. The upper limit of the time period of conducting the contact with ozone is typically 1 hour, and preferably 30 min.

The lower limit of the surface temperature of the substrate (P) when conducting the contact with ozone is typically greater than 0° C., and preferably 10° C. The upper limit of the surface temperature is typically less than 100° C., and preferably 40° C.

A procedure for the contact with ozone is exemplified by a procedure in which the substrate (P) is placed into a vessel into which the ozone-containing gas has been charged, and the like.

The contact with ozone may be conducted once, or a plurality of times.

Applying Step

In this step, the resist composition is applied onto the at least one surface of the substrate (P) treated by the treating step.

Resist Composition

The resist composition is exemplified by a radiation-sensitive resin composition containing a polymer having an acid-labile group and a radiation-sensitive acid generating agent (a chemically amplified resist composition), a positive tone resist composition containing an alkali-soluble resin and a quinone diazide-based photosensitizing agent, a negative tone resist composition containing an alkali-soluble resin and a crosslinking agent, a radiation-sensitive composition containing a metal-containing compound (metal resist composition), and the like. Of these, the radiation-sensitive resin composition is preferred. In a case in which the radiation-sensitive resin composition is used, formation of a positive tone pattern is enabled by developing with an alkaline developer solution, whereas formation of a negative tone pattern is enabled by developing with an organic solvent developer solution. For forming the resist pattern, procedures for fine pattern formation such as double patterning, double exposure, or the like may be appropriately employed.

The polymer contained in the radiation-sensitive resin composition may have, in addition to a structural unit that includes the acid-labile group, for example, a structural unit that includes a lactone structure, a cyclic carbonate structure, and/or a sultone structure; a structural unit that includes an alcoholic hydroxyl group; a structural unit that includes a phenolic hydroxyl group; a structural unit that includes a fluorine atom, etc. When the polymer has the structural unit that includes a phenolic hydroxyl group and/or the structural unit that includes a fluorine atom, further improvement in the sensitivity of the exposure to the extreme ultraviolet ray or the electron beam is enabled.

The lower limit of a solid content concentration of the resist composition is preferably 0.1% by mass, and more preferably 1% by mass. The upper limit of the solid content concentration is preferably 50% by mass, and more preferably 30% by mass. A resist composition filtered through a filter having a pore size of no greater than 0.2 μm may be suitably used. In the resist pattern-forming method, a commercially available resist composition may be directly used as the resist composition. The “solid content concentration” of the resist composition as referred to herein means a value (% by mass) as determined by: baking 0.5 g of the resist composition at 250° C. for 30 min; measuring the mass of the solid content in the resist composition; and dividing the mass of the solid content by the mass of the resist composition.

A procedure for applying the resist composition onto the at least one surface of the substrate (P) may be exemplified by a conventional procedure such as, e.g., spin coating. In applying the resist composition by spin coating, a number of times to spin the substrate (P) is adjusted such that the resist film to be obtained has a predetermined film thickness.

By prebaking a coating film of the resist composition, the resist film is formed by allowing the solvent in the coating film to be volatilized. A prebaking temperature may be appropriately adjusted depending on the type, etc., of the resist composition used. However, the lower limit of the prebaking temperature is preferably 30° C., and more preferably 50° C., whereas the upper limit of the prebaking temperature is preferably 200° C., and more preferably 150° C.

Exposing Step

In this step, the resist film formed by the applying step is exposed to the extreme ultraviolet ray or the electron beam. The exposure may be carried out by selectively irradiating with a radioactive ray through a mask, for example.

Developing Step

In this step, the resist film exposed is developed. This allows the resist pattern to be formed.

The developing may be a development with an alkali or a development with an organic solvent. According to the resist pattern-forming method, the sensitivity of the exposure to the extreme ultraviolet ray or the electron beam can be increased; therefore, in a case of using the radiation-sensitive resin composition as the resist composition, generation of a residue of the resist film is inhibited for a positive tone resist pattern obtained by the development with the alkali, leading to superior resolution; and a negative tone resist pattern obtained by the development with the organic solvent leads to a collapse-inhibiting property being superior. In this way, according to the resist pattern-forming method, forming of a favorable resist pattern is enabled.

Examples of the alkaline developer solution include alkaline aqueous solutions of sodium hydroxide, potassium hydroxide, sodium carbonate, sodium silicate, sodium metasilicate, ammonia, ethylamine, n-propylamine, diethylamine, di-n-propylamine, triethylamine, methyldiethylamine, dimethylethanolamine, triethanolamine, tetramethylammonium hydroxide (TMAH), tetraethylammonium hydroxide, pyrrole, piperidine, choline, 1,8-diazabicyclo[5.4.0]-7-undecene, and 1,5-diazabicyclo[4.3.0]-5-nonene; and the like. Further, appropriate amounts of water-soluble organic solvents such as alcohols such as methanol and ethanol; surfactants; and the like may be added to these alkaline aqueous solutions.

The organic solvent developer solution is exemplified by liquids in which a principle component is an organic solvent such as a ketone solvent, an alcohol solvent, an amide solvent, an ether solvent, or an ester solvent; and the like. Examples of these solvents include those similar to the solvents exemplified as the solvent (B) of the metal-containing composition (X), and more specific examples include n-butyl acetate, isobutyl acetate, sec-butyl acetate, amyl acetate, and the like. These solvents may be used either alone of one type, or as a mixture of multiple types thereof.

After the developing has been conducted with a developer solution (the alkaline developer solution or the organic solvent developer solution), a predetermined resist pattern corresponding to a mask can be obtained by preferably washing and then drying the resist pattern.

Etching Step

In this step, by using the resist pattern formed by the developing step as a mask, the substrate is etched. More specifically, a patterned substrate is obtained by etching once or a plurality of times, with the resist pattern as a mask.

In a case in which the substrate (P) has an organic underlayer film and the metal-containing film (T) formed on the base material, a pattern is formed on the base material by: etching the metal-containing layer (T) with the resist pattern as a mask to form a metal-containing layer pattern; etching the organic underlayer film with the metal-containing layer pattern as a mask to form an organic underlayer film pattern; and etching the base material with the organic underlayer film pattern as a mask.

Organic Underlayer Film

In the substrate (P), the organic underlayer film may be provided between the base material and the metal-containing layer (T). The organic underlayer film differs from the metal-containing layer (T). The organic underlayer film serves in further supplementing a function exhibited by the metal-containing layer (T) and/or the resist film in resist pattern forming, as well as in imparting a necessary specific function for attaining a function not exhibited by the metal-containing layer (T) and/or the resist film (for example, an antireflective property, coating film flatness, or high etching resistance to fluorine-based gas).

The organic underlayer film is exemplified by an antireflective film and the like. An exemplary antireflective film-forming composition may include “NFC HM8006,” available from JSR Corporation, and the like.

The organic underlayer film may be formed by applying an organic-underlayer film-forming composition through spin coating or the like to form a coating film, followed by heating.

The etching may be either dry etching or wet etching, and dry etching is preferred.

The dry etching may be carried out by using, for example, a known dry etching apparatus. An etching gas used for the dry etching may be appropriately selected depending on element composition and the like of the metal-containing layer (T) and the organic underlayer film to be etched. Examples of the etching gas which may be used include: fluorine-based gases such as CHF₃, CF₄, C₂F₆, C₃F₈ and SF₆; chlorine-based gases such as Cl₂ and BCl₃; oxygen-based gases such as O₂, O₃, and H₂O; reductive gases such as H₂, NH₃, CO, CO₂, CH₄, C₂H₂, C₂H₄, C₂H₆, C₃H₄, C₃H₆, C₃H₈, HF, HI, HBr, HCl, NO, NH₃ and BCl₃; inert gases such as He, N₂ and Ar; and the like. These gases may be used as a mixture. In dry etching of the metal-containing layer (T), the fluorine-base gas is typically used, and a mixture obtained by adding an oxygen-based gas and an inert gas may be suitably used. Further, in dry etching of the organic underlayer film, the oxygen-based gas is typically used.

### Substrate-Treating Method

The substrate-treating method is for use in forming a resist pattern by exposure to an extreme ultraviolet ray or an electron beam, wherein a substrate having the metal element in at least one surface layer is treated, the substrate-treating method including: treating the at least one surface of the substrate, the at least one surface containing the metal element, wherein the treating is one, or two or more of exposure to the ultraviolet ray, exposure to plasma, contact with water, contact with the alkali, contact with the acid, contact with hydrogen peroxide, and contact with ozone.

The substrate-treating method has been described above as the treating step in the aforementioned resist pattern-forming method.

### EXAMPLES

Examples of the present invention will be demonstrated below. It is to be noted that the following Examples merely illustrate one typical example of the present invention, and the scope of the present invention should not be construed to be narrowed by the Examples.

In the present Examples, measurements of: the solid content concentration of a solution of the compound (A); the weight average molecular weight (Mw) of the compound (A); and the average thickness of the film were conducted according to the following procedures.

Solid Content Concentration of Solution of Compound (A)

A solid content concentration (% by mass) of the solution of the compound (A) was calculated by baking 0.5 g of the solution of the compound (A) at 250° C. for 30 min to measure a mass of a solid content in 0.5 of the solution, and dividing the mass of the solid content by the mass of the solution of the compound (A).

Weight Average Molecular Weight (Mw)

Measurements were carried out by gel permeation chromatography (detector: differential refractometer) by using GPC columns (“AWM-H”×2, “AW-H”×1, and “AW2500”×2, available from Tosoh Corporation) under an analytical condition involving: a flow rate of 0.3 mL/min; an elution solvent of a mixture prepared by adding LiBr (30 mM) and citric acid (30 mM) to N,N′-dimethylacetamide; and a column temperature of 40° C., with mono-dispersed polystyrene as a standard.

Average Thickness of Film

The average thickness of the film was measured by using a spectroscopic ellipsometer (“M2000D,” available from J.A. Woollam Co.).

### Preparation of Metal-Containing Composition

Synthesis of Compound (A)

Metal-containing compounds used for the syntheses of the compounds (A) are as presented below. It is to be noted that in the following Synthesis Examples, “parts by mass” means a value, provided that a total mass of the metal-containing compound used was 100 parts by mass, unless otherwise specified particularly.

M-1: diisopropoxybis(2,4-pentanedionato) titanium (IV) (a solution in 2-propanol with a concentration of 75% by mass)

M-2: dibutoxybis(ethylacetoacetate) zirconium (IV) (a solution in n-butanol with a concentration of 70% by mass)

### Synthesis Example 1: Synthesis of Compound (A-1)

In a reaction vessel, the compound (M-1) (100 parts by mass, excluding the solvent) was dissolved in 468 parts by mass of propylene glycol monoethyl ether. In the reaction vessel, 53 parts by mass of water were added dropwise over 10 min with stirring at room temperature (25° C. to 30° C.). Subsequently, the reaction was allowed at 60° C. for 2 hrs. After completion of the reaction, the interior of the reaction vessel was cooled to no greater than 30° C. To the reaction solution thus cooled were added 654 parts by mass of propylene glycol monoethyl ether. Thereafter, water, alcohol generated by the reaction, and excess propylene glycol monoethyl ether were removed by using an evaporator to give a solution of the compound (A-1) in propylene glycol monoethyl ether. The Mw of the compound (A-1) was 4,200. The solid content concentration of the propylene glycol monoethyl ether solution of the compound (A-1) was 7.6% by mass.

### Synthesis Example 2: Synthesis of Compound (A-2)

In a reaction vessel, the compound (M-2) (100 parts by mass, excluding the solvent) was dissolved in 1,325 parts by mass of propylene glycol monoethyl ether. In the reaction vessel, 7 parts by mass of water were added dropwise over 10 min with stirring at room temperature (25° C. to 30° C.). Subsequently, the reaction was allowed at 60° C. for 2 hrs. After completion of the reaction, the interior of the reaction vessel was cooled to no greater than 30° C. To the reaction solution thus cooled were added 981 parts by mass of propylene glycol monoethyl ether. Thereafter, water, alcohol generated by the reaction, and excess propylene glycol monoethyl ether were removed by using an evaporator to give a solution of the compound (A-2) in propylene glycol monoethyl ether. The Mw of the compound (A-2) was 2,400. The solid content concentration of the propylene glycol monoethyl ether solution of the compound (A-2) was 13.0% by mass.

Preparation of Metal-Containing Composition

Solvents (B) used in the preparation of the metal-containing compositions are as presented below.

(B) Solvent

B-1: propylene glycol monoethyl ether

B-2: propylene glycol monomethyl ether acetate

### Preparation Example 1-1

A metal-containing composition (X-1) was prepared by mixing: as the compound (A) (solid content), 2 parts by mass of (A-1); and as the solvent (B), 95 parts by mass of (B-1) (including the solvent (B-1) contained in the solution of the compound (A)) and 5 parts by mass of (B-2), and filtering through a filter having a pore size of 0.2 μm a solution thus obtained.

### Preparation Example 1-2

Metal-containing composition (X-2) was prepared by a similar operation to Preparation Example 1-1 except that the type and the content of each component were as shown in Table 1 below.

TABLE 1

| | | (A) Compound | | (B) Solvent | |
|---|---|---|---|---|---|
| | Metal- | | content | | content |
| | containing | | (parts | | (parts |
| | composition | type | by mass) | type | by mass) |
| Preparation | X-1 | A-1 | 2 | B-1/B-2 | 95/5 |
| Example 1-1 | | | | | |
| Preparation | X-2 | A-2 | 2 | B-1/B-2 | 95/5 |
| Example 1-2 | | | | | |

### Production of Substrate

Production of Substrate (JF-1)

A substrate (JF-1) was obtained by applying onto a silicon base material the metal-containing composition (X-1) prepared as above by spin coating with a spin coater (“CLEAN TRACK ACT8,” available from Tokyo Electron Limited) and heating at 220° C. for 60 sec, followed by cooling at 23° C. for 30 sec to form a metal-containing film having an average thickness of 30 nm.

Production of Substrate (JF-2)

A substrate (JF-2) was obtained by applying onto a silicon base material the metal-containing composition (X-2) prepared as above by spin coating with the spin coater and heating at 220° C. for 60 sec, followed by cooling at 23° C. for 30 sec to form a metal-containing film having an average thickness of 30 nm.

Production of Substrate (JF-3)

A substrate (JF-3) was obtained by forming a titanium oxide film having an average thickness of 5 nm on a silicon substrate by a chemical vapor deposition procedure.

### Preparation of Resist Composition

Resist compositions were prepared as in the following.

### Preparation Example 2-1

A resist composition (R-1) was obtained by mixing: 100 parts by mass of a polymer having a structural unit (1) derived from 4-hydroxystyrene, a structural unit (2) derived from styrene, and a structural unit (3) derived from 4-t-butoxystyrene (proportion of each structural unit contained: (1)/(2)/(3)=65/5/30 (mol %)); 2.5 parts by mass of triphenylsulfonium salicylate as a radiation-sensitive acid generating agent; and as solvents, 4,400 parts by mass of ethyl lactate and 1,900 parts by mass of propylene glycol monomethyl ether acetate, and filtering through a filter having a pore size of 0.2 μm a solution thus obtained.

### Substrate Treating

The substrates (JF-1) to (JF-3) produced as described above were each treated as indicated below by (P-1) or (P-2).

P-1: Water (20° C. to 25° C.) was brought into contact with the surface of the substrate using a puddle procedure, and then spinning was conducted with the spin coater to permit drying.

P-2: The surface of the substrate was exposed to an ultraviolet ray for 10 minutes in clean air. As a light source for the ultraviolet ray, an Xe excimer lamp (wavelength: 172 nm; 10 mW/cm²; available from Ushio Inc.) was used.

### Resist Pattern Forming by Exposure to Electron Beam

Development by Alkaline Developer Solution

### Examples 1-1 to 1-6 and Comparative Examples 1-1 to 1-3

The resist composition (R-1) was applied on the surface of each of the substrates, the surface having been treated by the treating method indicated in Table 2 below, and heated at 130° C. for 60 sec, followed by cooling at 23° C. for 30 sec, to form a resist film having an average thickness of 50 nm. Next, the resist film was irradiated with an electron beam by using an electron beam writer (“HL800D” available from Hitachi, Ltd.; output: 50 KeV; electric current density: 5.0 ampere/cm²). After the irradiation with the electron beam, the substrate was heated at 110° C. for 60 sec, followed by cooling at 23° C. for 60 sec. Thereafter, a development was carried out using a 2.38% by mass aqueous TMAH solution (20° C. to 25° C.) with a puddle procedure, followed by washing with water and drying to give a substrate for evaluation on which a resist pattern was formed. For line-width measurement and observation of the resist pattern on the substrate for evaluation, a scanning electron microscope (“S-9380,” available from Hitachi High-Technologies Corporation) was used.

### Evaluations

The sensitivity and the resolution were evaluated according to the following procedures. The results of the evaluations are shown in Table 2 below. In Table 2, “-” in the “Treating Method” column denotes that a corresponding substrate treating was not carried out.

Sensitivity

Upon the resist pattern forming, an exposure dose at which a hole pattern with a diameter of 100 nm was formed was defined as an optimum exposure dose. With respect to the Comparative Examples when similar substrates were used (Comparative Example 1-1 for Examples 1-1 and 1-2; Comparative Example 1-2 for Examples 1-3 and 1-4; and Comparative Example 1-3 for Examples 1-5 and 1-6), the sensitivity was evaluated to be: “A” (favorable) in a case of an increase in sensitivity being no less than 5%; and “B” (unfavorable) in a case of the increase in sensitivity being less than 5%. In Table 2, a standard for the evaluation is indicated by a denotation “-” in the “Sensitivity” column.

Resolution

When evaluating the resist patterns, an exposure dose at which a hole pattern with a diameter of 80 nm was formed was defined as an optimum exposure dose. For line-width measurement and observation of the resist pattern on the substrate for evaluation, a scanning electron microscope (“S-9380,” available from Hitachi High-Technologies Corporation) was used. On the hole pattern formed at the optimum exposure dose, the resolution was evaluated as: “A” (favorable) in a case of no resist film residue being identified; and “B” (unfavorable) in a case of resist film residue being identified.

TABLE 2

| | | Treating | | |
|---|---|---|---|---|
| | Substrate | method | Sensitivity | Resolution |
| Example 1-1 | JF-1 | P-1 | A | A |
| Example 1-2 | JF-1 | P-2 | A | A |
| Example 1-3 | JF-2 | P-1 | A | A |
| Example 1-4 | JF-2 | P-2 | A | A |
| Example 1-5 | JF-3 | P-1 | A | A |
| Example 1-6 | JF-3 | P-2 | A | A |
| Comparative | JF-1 | — | — | B |
| Example 1-1 | | | | |
| Comparative | JF-2 | — | — | B |
| Example 1-2 | | | | |
| Comparative | JF-3 | — | — | B |
| Example 1-3 | | | | |

### Resist Pattern Forming by Exposure to Electron Beam

Development by Organic Solvent Developer Solution

### Examples 2-1 to 2-6 and Comparative Examples 2-1 to 2-3

The resist composition (R-1) was applied on the surface of each of the substrates, the surface having been treated by the treating method indicated in Table 3 below, and heated at 130° C. for 60 sec, followed by cooling at 23° C. for 30 sec, to form a resist film having an average thickness of 50 nm. Next, the resist film was irradiated with an electron beam by using an electron beam writer (“HL800D,” available from Hitachi, Ltd.; output: 50 KeV; electric current density: 5.0 ampere/cm²). After the irradiation with the electron beam, the substrate was heated at 110° C. for 60 sec, followed by cooling at 23° C. for 60 sec. Thereafter, a development was carried out using butyl acetate (20° C. to 25° C.) with a puddle procedure, followed by drying to give a substrate for evaluation on which a resist pattern was formed. For line-width measurement and observation of the resist pattern on the substrate for evaluation, a scanning electron microscope (“S-9380,” available from Hitachi High-Technologies Corporation) was used.

### Evaluations

The sensitivity and a resist pattern collapse-inhibiting property were evaluated according to the following procedures. The results of the evaluations are shown in Table 3 below. In Table 3, “-” in the “Treating Method” column denotes that a corresponding substrate treating was not carried out.

Sensitivity

When evaluating the resist patterns, an exposure dose at which a 1:1 line-and-space with a line width of 150 nm was formed was defined as an optimum exposure dose. With respect to the Comparative Examples when similar substrates were used (Comparative Example 2-1 for Examples 2-1 and 2-2; Comparative Example 2-2 for Examples 2-3 and 2-4; and Comparative Example 2-3 for Examples 2-5 and 2-6), the sensitivity was evaluated to be: “A” (favorable) in a case of the increase in sensitivity being no less than 5%; and “B” (unfavorable) in a case of the increase in sensitivity being less than 5%. In Table 3, a standard for the evaluation is indicated by a denotation “-” in the “Sensitivity” column.

Resist Pattern Collapse-Inhibiting Property

Upon the resist pattern forming, an exposure dose at which a 1:1 line-and-space with a line width of 100 nm was formed was defined as an optimum exposure dose. The resist pattern collapse-inhibiting property was evaluated as: “A” (favorable) in a case of no collapse being identified; and “B” (unfavorable) in a case of collapse being identified, with regard to the resist pattern formed at the optimum exposure dose.

TABLE 3

| | | | | Resist pattern |
|---|---|---|---|---|
| | | Treating | | collapse- |
| | Substrate | method | Sensitivity | inhibiting property |
| Example 2-1 | JF-1 | P-1 | A | A |
| Example 2-2 | JF-1 | P-2 | A | A |
| Example 2-3 | JF-2 | P-1 | A | A |
| Example 2-4 | JF-2 | P-2 | A | A |
| Example 2-5 | JF-3 | P-1 | A | A |
| Example 2-6 | JF-3 | P-2 | A | A |
| Comparative | JF-1 | — | — | B |
| Example 2-1 | | | | |
| Comparative | JF-2 | — | — | B |
| Example 2-2 | | | | |
| Comparative | JF-3 | — | — | B |
| Example 2-3 | | | | |

As is clear from the results shown in Tables 2 and 3, according to the resist pattern-forming method of the Examples, forming a resist pattern having superior resolution with high sensitivity and a superior resist pattern collapse-inhibiting property was enabled.

### Resist Pattern Forming by Exposure to Extreme Ultraviolet Ray

Development by Alkaline Developer Solution

### Examples 3-1 to 3-6 and Comparative Examples 3-1 to 3-3

The resist composition (R-1) was applied on the surface of each of the substrates, the surface having been treated by the treating method indicated in Table 4 below, and heated at 130° C. for 60 sec, followed by cooling at 23° C. for 30 sec, to form a resist film having an average thickness of 50 nm. Next, the resist film was exposed to an extreme ultraviolet ray using an EUV scanner (“TWINSCAN NXE: 3300B,” available from ASML Co.; (NA=0.3; Sigma=0.9; quadrupole illumination, with a hole pattern mask having a diameter of 40 nm in terms of a dimension on wafer)). After the exposure, the substrate was heated at 110° C. for 60 sec, followed by cooling at 23° C. for 60 sec. Thereafter, a development was carried out using a 2.38% by mass aqueous TMAH solution (20° C. to 25° C.) with a puddle procedure, followed by washing with water and drying to give a substrate for evaluation on which a resist pattern was formed.

### Evaluations

The sensitivity and resolution were evaluated according to the following procedures. The results of the evaluations are shown in Table 4 below. In Table 4, “-” in the “Treating Method” column denotes that a corresponding substrate treating was not carried out.

Sensitivity

For line-width measurement and observation of the resist pattern on the substrate for evaluation, a scanning electron microscope (“CG-4000,” available from Hitachi High-Technologies Corporation) was used. For the substrate for evaluation, an exposure dose at which a hole pattern with a diameter of 40 nm was formed was defined as an optimum exposure dose. With respect to the Comparative Examples when similar substrates were used (Comparative Example 3-1 for Examples 3-1 and 3-2; Comparative Example 3-2 for Examples 3-3 and 3-4; and Comparative Example 3-3 for Examples 3-5 and 3-6), the sensitivity was evaluated to be: “A” (favorable) in a case of the increase in sensitivity being no less than 5%; and “B” (unfavorable) in a case of the increase in sensitivity being less than 5%. In Table 4, a standard for the evaluation is indicated by a denotation “-” in the “Sensitivity” column.

Resolution

For line-width measurement and observation of the resist pattern on the substrate for evaluation, a scanning electron microscope (“CG-4000,” available from Hitachi High-Technologies Corporation) was used. For the substrate for evaluation, an exposure dose at which a hole pattern with a diameter of 40 nm was formed was defined as an optimum exposure dose. On the hole pattern formed at the optimum exposure dose, the resolution was evaluated as: “A” (favorable) in a case of no resist film residue being identified; and “B” (unfavorable) in a case of resist film residue being identified.

TABLE 4

| | | Treating | | |
|---|---|---|---|---|
| | Substrate | method | Sensitivity | Resolution |
| Example 3-1 | JF-1 | P-1 | A | A |
| Example 3-2 | JF-1 | P-2 | A | A |
| Example 3-3 | JF-2 | P-1 | A | A |
| Example 3-4 | JF-2 | P-2 | A | A |
| Example 3-5 | JF-3 | P-1 | A | A |
| Example 3-6 | JF-3 | P-2 | A | A |
| Comparative | JF-1 | — | — | B |
| Example 3-1 | | | | |
| Comparative | JF-2 | — | — | B |
| Example 3-2 | | | | |
| Comparative | JF-3 | — | — | B |
| Example 3-3 | | | | |

### Resist Pattern Forming by Extreme Ultraviolet Ray

Development by Organic Solvent Developer Solution

### Examples 4-1 to 4-6 and Comparative Examples 4-1 to 4-3

The resist composition (R-1) was applied on the surface of each of the substrates, the surface having been treated by the treating method indicated in Table 5 below, and heated at 130° C. for 60 sec, followed by cooling at 23° C. for 30 sec, to form a resist film having an average thickness of 50 nm. Next, the resist film was exposed to an extreme ultraviolet ray using an EUV scanner (“TWINSCAN NXE: 3300B,” available from ASML Co.; (NA=0.3; Sigma=0.9; quadrupole illumination, with a 1:1 line-and-space mask having a line width of 25 nm in terms of a dimension on wafer)). After the exposure, the substrate was heated at 110° C. for 60 sec, followed by cooling at 23° C. for 60 sec. Subsequently, a development was carried out using butyl acetate (20° C. to 25° C.) with a puddle procedure, followed by drying to give a substrate for evaluation on which a resist pattern was formed.

### Evaluations

The sensitivity and the resist pattern collapse-inhibiting property were evaluated according to the following procedures. The results of the evaluations are shown in Table 5 below. In Table 5, “-” in the “Treating Method” column denotes that a corresponding substrate treating was not carried out.

Sensitivity

For line-width measurement and observation of the resist pattern on the substrate for evaluation, a scanning electron microscope (“CG-4000,” available from Hitachi High-Technologies Corporation) was used. For the substrate for evaluation, an exposure dose at which a 1:1 line-and-space with a line width of 25 nm was formed was defined as an optimum exposure dose. With respect to the Comparative Examples when similar substrates were used (Comparative Example 4-1 for Examples 4-1 and 4-2; Comparative Example 4-2 for Examples 4-3 and 4-4; and Comparative Example 4-3 for Examples 4-5 and 4-6), the sensitivity was evaluated to be: “A” (favorable) in a case of the increase in sensitivity being no less than 5%; and “B” (unfavorable) in a case of the increase in sensitivity being less than 5%. In Table 5, a standard for the evaluation is indicated by a denotation “-” in the “Sensitivity” column.

Resist Pattern Collapse-Inhibiting Property

For line-width measurement and observation of the resist pattern on the substrate for evaluation, a scanning electron microscope (“CG-4000,” available from Hitachi High-Technologies Corporation) was used. For the substrate for evaluation, an exposure dose at which a 1:1 line-and-space with a line width of 25 nm was formed was defined as an optimum exposure dose. The resist pattern collapse-inhibiting property was evaluated as: “A” (favorable) in a case of no collapse being identified; and “B” (unfavorable) in a case of collapse being identified, with regard to the resist pattern formed at the optimum exposure dose.

TABLE 5

| | | | | Resist pattern |
|---|---|---|---|---|
| | | Treating | | collapse- |
| | Substrate | method | Sensitivity | inhibiting property |
| Example 4-1 | JF-1 | P-1 | A | A |
| Example 4-2 | JF-1 | P-2 | A | A |
| Example 4-3 | JF-2 | P-1 | A | A |
| Example 4-4 | JF-2 | P-2 | A | A |
| Example 4-5 | JF-3 | P-1 | A | A |
| Example 4-6 | JF-3 | P-2 | A | A |
| Comparative | JF-1 | — | — | B |
| Example 4-1 | | | | |
| Comparative | JF-2 | — | — | B |
| Example 4-2 | | | | |
| Comparative | JF-3 | — | — | B |
| Example 4-3 | | | | |

As is clear from the results shown in Tables 4 and 5, according to the resist pattern-forming method of the Examples, a resist pattern having superior resolution with high sensitivity and a superior resist pattern collapse-inhibiting property can be formed.

The resist pattern-forming method and the substrate-treating method of the embodiments of the present invention enable a resist pattern superior in resolution to be obtained with high sensitivity. Accordingly, these can be suitably used for extreme ultraviolet ray lithography or electron beam lithography, as well as for manufacture of semiconductor devices, for which microfabrication is expected to progress further hereafter, and the like.

Obviously, numerous modifications and variations of the present invention are possible in light of the above teachings. It is therefore to be understood that within the scope of the appended claims, the invention may be practiced otherwise than as specifically described herein.

What is claimed is:

1. A resist pattern-forming method comprising:
treating a surface layer of a substrate with an ultraviolet ray, plasma, water, an alkali, an acid, hydrogen peroxide, ozone, or a combination thereof, the surface layer comprising at least one metal element;
applying a resist composition on a surface of the surface layer to provide a resist film directly or indirectly on the surface;
exposing the resist film to an extreme ultraviolet ray or an electron beam; and
developing the resist film exposed.

2. The resist pattern-forming method according to claim 1, wherein the at least one metal element belongs to period 3 to period 7 of group 3 to group 15 in periodic table.

3. The resist pattern-forming method according to claim 2, wherein the at least one metal element belongs to group 4 in the periodic table.

4. The resist pattern-forming method according to claim 3, wherein the at least one metal element is titanium, zirconium, or a combination thereof.

5. The resist pattern-forming method according to claim 1, wherein the surface layer is treated with the water before the applying of the resist composition.

6. The resist pattern-forming method according to claim 1, wherein the surface layer is treated with the ultraviolet ray before the applying of the resist composition.

7. The resist pattern-forming method according to claim 1, wherein the substrate comprises a base material and the surface layer.

8. The resist pattern-forming method according to claim 7, wherein the base material is a silicon wafer coated with a low-dielectric insulating film.

9. The resist pattern-forming method according to claim 7, further comprising applying a metal-containing compound on the base material to form the surface layer, wherein the metal-containing compound is a metal compound having a hydrolyzable group, a hydrolysis product of the metal compound, a hydrolytic condensation product of the metal compound, or a combination thereof.

10. The resist pattern-forming method according to claim 3, wherein the surface layer is treated with the water before the applying of the resist composition.

11. The resist pattern-forming method according to claim 3, wherein the surface layer is treated with the ultraviolet ray before the applying of the resist composition.

12. The resist pattern-forming method according to claim 3, wherein the substrate comprises a base material and the surface layer.

13. The resist pattern-forming method according to claim 12, wherein the base material is a silicon wafer coated with a low-dielectric insulating film.

14. The resist pattern-forming method according to claim 12, further comprising applying a metal-containing compound on the base material to form the surface layer, wherein the metal-containing compound is a metal compound having a hydrolyzable group, a hydrolysis product of the metal compound, a hydrolytic condensation product of the metal compound, or a combination thereof.

15. A substrate-treating method comprising:
treating a surface layer of a substrate on which a resist pattern is to be formed by exposure to an extreme ultraviolet ray or an electron beam, with an ultraviolet ray, plasma, water, an alkali, an acid, hydrogen peroxide, ozone, or a combination thereof, the surface layer comprising at least one metal element.
